(19) United States
(12) Patent Application Publication
(10) Pub. No.: US 2007/0074662 A1
(43) Pub. Date: Apr. 5, 2007

(54) Plasma processing apparatus for forming film containing carbons on object to be deposited

(75) Inventor: Toshiyuki Hirota, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/540,597

(22) Filed: Oct. 2, 2006

(30) Foreign Application Priority Data
Oct. 3, 2005 (JP) 2005-290125

(51) Int. Cl. C23C 16/00

(52) U.S. Cl. 118/715; 118/723 R

(57) ABSTRACT

There is disclosed a plasma processing apparatus for making a gas including hydrocarbon plasma and forming a film including carbons on an object to be coated with a film. The apparatus includes a first reaction chamber for performing a first plasma process on the object to be deposited, a second reaction chamber for performing a second plasma process on an exhaust gas after the first plasma process is performed, and an exhaust pump for exhausting a gas to the outside after the second plasma process is performed. The first reaction chamber is connected to the exhaust pump via the second reaction chamber.

### BACKGROUND OF THE INVENTION

1. Field of the Invention

The present invention relates to a plasma processing apparatus, and in particular, relates to an apparatus equipped with a mechanism for suppressing deposition of a carboniferous by-product in a reaction chamber and a pipe of a vacuum pumping system pipe and a mechanism for cleaning the by-product thereof.

2. Description of the Related Art

In recent years, a carboniferous film (hereinafter, carbon film) that can be formed by the plasma CVD method has been used as a hard mask that can be subjected to ashing, for the patterning process of a semiconductor integrated circuit. The carbon film is formed with, for example, a parallel plate type plasma processing apparatus, as schematically shown in FIG. 1.

Hereinafter, explanations are given of the arrangement of the processing apparatus in FIG. 1 and the process for forming a film with this apparatus.

As shown in FIG. 1, plasma processing apparatus 300 is broadly divided into reaction chamber 301 to be a space in which a film is formed, a supply system for supplying a predetermined gas to reaction chamber 301, and an exhaust system for exhausting the gas from reaction chamber 301. Also, plasma processing apparatus 300 is provided with control means that performs a sequence for forming a film (hereinafter, film formation sequence) and that performs a cleaning sequence, which will be described later.

Reaction chamber 301 has, for example, a cylinder-shaped internal space. In the interior thereof, stage 302 that supports substrate 303, which is an object to be filmed (, or an objected to be coated with a film), and shower plate 308, that is arranged at the upper side of stage 302, are arranged. The electric power from RF power source 307 is supplied to shower plate 308 through an impedance matching box, not shown.

Stage 302 also serves as an anode electrode of the parallel plate electrode, and shower plate 308 also serves as a cathode electrode to be paired. A heater is built in stage 302, and stage 302 is heated, for example, about 150 to 550° C., when used. In the arrangement in FIG. 1, stage 302 is arranged to be movable up and down, and when stage 302 is positioned at the lower end, substrate 303 is loaded on the upper surface of stage 302. Specifically, substrate 303 is arranged on stage 302 through slit valve 305, and then stage 302 moves up.

For the supply system, gas line 309 for introducing a hydro carboniferous (CxHy) source gas into the reaction chamber together with a carrier gas, such as helium, gas line 311 for introducing oxygen, and gas line 314 for introducing hydrogen are arranged.

For the exhaust system, exhaust chamber 304 that surrounds reaction chamber 301 and is formed in a doughnut shape, exhaust pump 324 used to discharge the gas from exhaust chamber 304 to the outside, and the like are arranged. Exhaust chamber 304 and exhaust pump 324 are connected by exhaust pipe 332, and main exhaust valve 322 and pressure control valve 323 are arranged in exhaust pipe 332.

Incidentally, the gas drawn to exhaust pump 324 is sent to the outside through exhaust port 325. Also, since exhaust chamber 304 is formed to surround reaction chamber 301, discharge of reaction chamber 301 can be performed evenly, for example, compared to the arrangement in which an exhaust port is formed only at a part of the periphery of the reaction chamber.

Plasma processing apparatus 300 in accordance with the above-mentioned arrangement is used as follows. First, substrate 303, which is the object to be coated with a film, is arranged on stage 302 through slit valve 305. Thereafter, the height of stage 302 is adjusted and substrate 303 rises to the position opposite to shower plate 308. Also, the heater in stage 302 is operated according to predetermined timing, and stage 302 is heated.

Successively, hydro carboniferous source gas is introduced from gas line 309 into reaction chamber 301. The introduced gas is supplied onto substrate 303 through shower plate 308, as indicated by arrows in FIG. 1. After the gas is supplied, the RF voltage is applied between stage 302 (, or anode) and shower plate 308 (, or cathode). According to this arrangement, plasma 306 is generated, the introduced hydro carboniferous gas molecules are polymerized, and a carbon film is formed on the surface of substrate 303. Incidentally, unnecessary gas existing in reaction chamber 301 is sent to the outside through exhaust chamber 304 and exhaust pipe 322 while exhaust pump 324 is used as a driving source.

Now, when the process for forming a carbon film (hereinafter, film formation process) is performed, as described above, adherents are deposited not only on the surface of the substrate but also on unnecessary portions, such as the internal wall of reaction chamber 301 and the internal wall of exhaust pipe 322. The adherents, which are deposited like this, are apt to come off as the film formation process is advanced. When the adherents that come off scatter and adhered to substrate 303, which is the object to be coated with a film, these may become a cause of particle generation. So, in order to solve such a problem, conventionally, cleaning is performed whenever the film formation process is performed at predetermined times, and the adherents deposited in reaction chamber 301 and exhaust pipe 332 are removed.

In regard to this cleaning process, specifically, there is the method in which the process is performed with oxygen plasma, the method in which the process is performed with plasma that is generated by using a mixed gas of oxygen and hydrogen, and the method in which the process is performed with hydrogen plasma (reducing atmosphere) after the process is performed with oxygen plasma (oxidizing atmosphere) (see Japanese Patent Laid-open Nos. 1995-78802 and 2004-296512, concerning these methods).

An example is briefly explained. First, pressure control valve 323 is operated to set the pressure to several Torr while oxygen is introduced from gas line 314 into the reaction chamber. Then, the RF voltage is applied between shower plate 308 and stage 302 to generate oxygen plasma. In accordance with the oxygen radicals that are generated by applying the RF voltage, the adherents deposited on the surface of shower plate 308, stage 302, and on the internal wall of reaction chamber 301 are subjected to ashing and are removed.

However, according to the above-mentioned method, though the adherents that are near portions that are directly exposed to plasma in the reaction chamber can be removed, the adherents on the portions that are not directly exposed to plasma in the reaction chamber, exhaust chamber 304, and on the internal wall of exhaust system pipe 332 are difficult to be removed.

In particular, the adherents in light brown powder form and black tar form that originated from hydrocarbon polymer formed in the gas phase are formed in exhaust system pipe 332 and adhere to pressure control valve 323 and main exhaust valve 322 between the reaction chamber and the exhaust pump. In order to prevent a harmful effect by these adherents, the reaction chamber and the exhaust pipe are disassembled and maintenance, like wet cleaning, is regularly performed in some cases. However, when wet cleaning is frequently performed, it causes a lowering of the operating rate and an increase in the manufacturing cost.

On the other hand, the cleaning time during the cleaning sequence is lengthened, thereby suppressing deposition of the adherents in the exhaust system pipe to some extent. However, it takes time to perform cleaning in itself, and the throughput of the apparatus as a whole is remarkably lowered.

### SUMMARY OF THE INVENTION

It is an object of the present invention to provide a plasma processing apparatus for forming a carbon film, without sacrificing throughput, to minimize deposition of adherents (such as carboniferous depositions) in the exhaust system with little need of wet cleaning at high operating rate.

In the plasma processing apparatus of the present invention, the apparatus includes a first reaction chamber for performing a first plasma process on the object to be deposited, a second reaction chamber for performing a second plasma process on an exhaust gas after the first plasma process is performed, and an exhaust pump for exhausting a gas to the outside after the second plasma process is performed. Then, the first reaction chamber is connected to the exhaust pump via the second reaction chamber.

With the above arrangement, in the second chamber, hydrocarbon polymers in the exhaust gas from the first reaction chamber can be decomposed. Therefore, the amount of products that adhere to the valves and the exhaust pump arranged in the exhaust pipe between the second reaction chamber and the exhaust pump can be minimized. Also, oxidation is performed by oxidizing radicals generated from the second reaction chamber in the portions where oxidizing radicals that are generated from the first reaction chamber by cleaning are hard to reach when the first reaction chamber is cleaned, and thus deposition of adherents to the exhaust pipe, the valve, and the like can be prevented.

According to the present invention, as described above, the apparatus can be carried out in which deposition of adherents to the exhaust pipe and the like can be prevented, throughput is high, maintenance frequency is minimized and there is high reliability.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a view semantically showing the section of the plasma processing apparatus of the conventional art;

FIG. 2 is a view semantically showing the section of the plasma processing apparatus according to the first embodiment of the present invention; and

FIG. 3 is a view semantically showing the section of the plasma processing apparatus according to the second embodiment of the present invention.

### DESCRIPTION OF THE PREFERRED EMBODIMENTS

This application is based upon and claims the benefit of priority from Japanese Patent Application No.2005-290125 filed on Oct. 3. 2005, the content of which is incorporated by reference.

### First Exemplary Embodiment

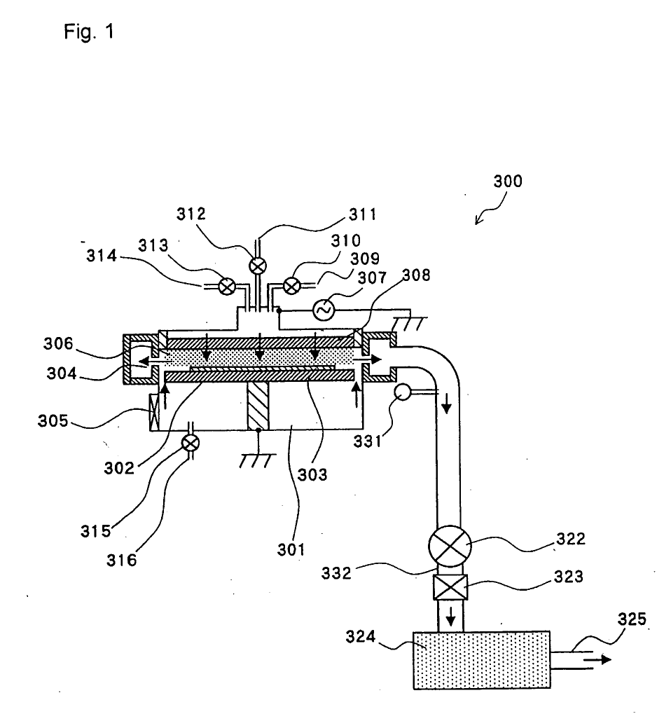

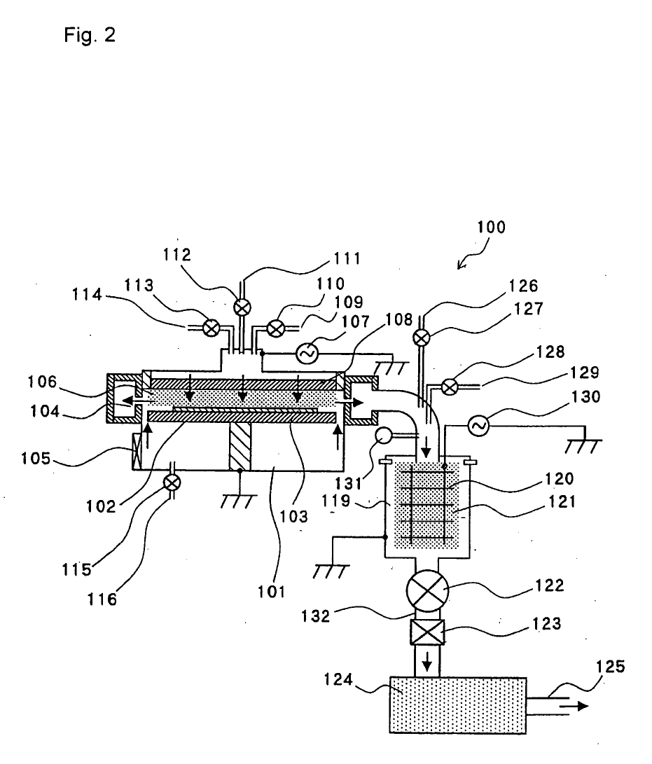

Referring to FIG. 2, the main feature of plasma processing apparatus 100 according to the first embodiment is that reaction chamber 119 is arranged between another reaction chamber 101 and main exhaust valve 122, and the others are similar to those of conventional processing apparatus 300 shown in FIG. 1. Incidentally, in FIG. 2, numeral references corresponding to the numeral references in FIG. 1 are given to the elements having the same functions as processing apparatus 300, and overlapping explanations are omitted.

Reaction chamber 119 (second reaction chamber) is formed in a cylinder shape, and, plasma 121 is generated with predetermined timing therein, as described later. To carry out this, cathode 120 is arranged in reaction chamber 119, and power from RF power source 130 is supplied through cathode 120. Also, two gas lines 126, 129 are connected to exhaust pipe 132 upstream of reaction chamber 119, oxygen is introduced from one gas line 126, and hydrogen is introduced from another gas line 129. Pressure sensor 131 is attached near the position where gas lines 126, 129 are connected, and detects pressure in the pipe.

Incidentally, plasma 121 generated in reaction chamber 119 oxidizes the exhaust gas from reaction chamber 101. In the present invention, the exhaust gas is oxidized by the operation of plasma 121, in this way, and is converted into a substance that is hard to be deposited, such as CO₂ and H₂O, thereby suppressing deposition of adherents.

The use method of processing apparatus 100, according to the first embodiment, based on above-mentioned arrangement, is explained when the process is divided into a film formation sequence and a cleaning sequence.

First, in the film formation sequence, substrate 103 is introduced from slit valve 105 and is put on stage 102, similar to the conventional art. After that, stage 102 moves upward, substrate 103 is arranged at a predetermined position opposite to shower plate 108, and stage 102 is heated at predetermined timing.

Successively, oxygen is introduced from gas line 126 into reaction chamber 119, for example, at a gas flow of 1000 sccm (standard ml/min), and the gas in the reaction chamber is controlled to a predetermined pressure by using pressure sensor 131 and pressure control valve 123. Then, RF electric power, for example, of 500 W is introduced into reaction chamber 119 from cathode electrode 120. In accordance with this arrangement, plasma 121 is generated in reaction chamber 119.

A hydro carboniferous source gas is introduced into reaction chamber 101 through gas line 109 together with a carrier gas, such as helium. The introduced gas is supplied onto the substrate through shower plate 108. As to the source gas, for example, methane, ethylene, and propylene are available. For example, helium of 1000 sccm and ethylene 1500 sccm may be supplied from gas line 109 and the pressure may be controlled to 7 Torr (1 Torr=133.322 Pa). Naturally, the pressure is not limited to 7 Torr, and may be set in the range from 1 to 10 Torr, as appropriate.

Now, since hydrocarbon is flammable and oxygen increases the susceptibility of substances to burn, plasma processing apparatus 100 according to the present invention is arranged as follows for safety. Specifically, when the pressure is 50 Torr or less and no plasma is generated, final valve 110 of gas line 109 and final valve 127 of gas line 126 are not opened simultaneously. This arrangement can be carried out by an interlock mechanism, and hydrocarbon and oxygen are not supplied simultaneously according to this arrangement. In other words, only when oxygen plasma is generated in reaction chamber 119 under a reduced pressure state of 50 Torr or less, is hydrocarbon supplied.

Successively, the RF voltage, for example, of 1500 W is applied between stage 102 and shower plate 108, and plasma 106 is generated in reaction chamber 101. In accordance with this arrangement, the introduced hydro carboniferous gas molecules are polymerized and a carbon film is formed on the surface of substrate 103. Incidentally, unnecessary gas existing in reaction chamber 101 is sent to exhaust pipe 132 through exhaust chamber 104.

Exhaust gas that is successively sent passes through reaction chamber 119. The exhaust gas mainly includes unreacted hydrocarbons, and particles that have been polymerized in a vapor phase. These are almost completely oxidized by plasma 121 in reaction chamber 119 and converted into substances that are hard to be deposited, such as CO₂ and H₂O. According to the processing apparatus of the first embodiment, since the exhaust gas is oxidized in reaction chamber 119 that is newly arranged, in this way, the amount of products that adhere to main exhaust valve 122 and pressure control valve 123 at the subsequent stage can be minimized.

The subsequent steps can be performed, similarly to the conventional art. Specifically, after a carbon film is deposited to a desired film thickness, the power supply from RF power source 107 is stopped in order to stop a formation of a carbon film, so generation of plasma 106 is stopped. Subsequently, supply of hydrocarbon to reaction chamber 101 is stopped and generation of plasma in reaction chamber 119 and supply of oxygen from gas line 129 are stopped. Then, stage 102 is moved to the conveyance position (lower end position), and substrate 103 is carried outside reaction chamber 101 through slit valve 105.

Processing apparatus 100 according to the first embodiment can suppress deposition of adherents downstream of reaction chamber 119, as described above. However, adherents are deposited on the elements between reaction chamber 101 and reaction chamber 119. Therefore, in order to adverse effects caused by these adherents, the processing apparatus of the present invention performs a cleaning sequence as follows. Incidentally, the cleaning sequence may be performed whenever the film formation sequence is performed for predetermined number of times. However, there is no limitation in this way.

In the cleaning sequence, first, oxygen is each introduced into each of two reaction chambers 101, 119 from gas line 111 and gas line 126, and the pressure is adjusted to a desired level by using pressure sensor 131 and pressure control valve 123.

Successively, RF electric power (for example, 500 W) is supplied to shower plate 108 and cathode 120 from RF power sources 107, 130. In accordance with this arrangement, plasma containing oxygen is generated. Then, oxygen radicals and the like are generated with this plasma, and products mainly including carbon deposited in the reaction cambers are removed by using these oxygen radicals. Specifically, the pressure may be controlled to 4 Torr by pressure control valve 123 while oxygen is introduced from gas line 114, RF electric power (for example, 500 W) may be applied between shower plate 108 and stage 102 to generate oxygen plasma. Through the use of these oxygen radicals, carbon films that are adhered to the surface of shower plate 108, stage 102, and the internal wall of reaction chamber 101 are removed.

Incidentally, most of the adherents that are oxidized by the oxygen radicals become CO₂ and H₂O. However, a part thereof reacts in the plasma again and becomes the origin of another product that can be easily to be deposited, represented by a carboxyl group [COOH], in some cases. Even if such a substance is generated upstream of reaction chamber 119, this substance is almost completely oxidized when passing through reaction chamber 119, and thus adherents are prevented from being deposited on the elements downstream of reaction chamber 119.

In order to terminate the cleaning sequence, plasma generation in reaction chambers 101, 119 may be stopped and oxygen introduction into each reaction chamber may be stopped. However, there is no limitation in this way.

### Second Exemplary Embodiment

The first embodiment describes the example in which oxygen plasma is mainly used to suppress deposition of unnecessary carbon. On the other hand, conventionally, the technique for adding hydrogen to oxygen plasma is known. In comparison with oxygen radicals, hydroxyl radicals that are generated by adding hydrogen provide stronger oxidizing power and a longer lifetime in the vapor phase. Therefore, the addition of hydrogen is helpful for enabling an effective exhaust gas process and effective cleaning. Hydrogen can be also added in the plasma processing apparatus of the second embodiment in the same way. However, because of the feature of the present invention, the film formation sequence and the cleaning sequence are provided to meet the arrangement, and this becomes the feature of the plasma processing apparatus of the present invention.

Hereinafter, the feature is explained while divided into the film formation sequence and the cleaning sequence. Incidentally, explanations are omitted of the same steps as the first embodiment. Also, the apparatus in itself is similar to that of the first embodiment.

In the second embodiment, oxygen is introduced into reaction chamber 119 through gas line 126 (similar to the first embodiment), and hydrogen is supplied into reaction chamber 119 after plasma 121 is generated by applying the RF electric power, for example, of 1500 W to cathode electrode 120. Specifically, hydrogen is supplied from gas line 129, for example, at a gas flow of 40 sccm.

Now, since hydrogen is flammable and oxygen increases the susceptibility of substances to burn, plasma processing apparatus 100 according to the present invention is arranged as follows for safety. Specifically, when the pressure is 50 Torr or less and no plasma is generated, an interlock mechanism is provided to prevent final valve 110 and final valve 127 from being opened simultaneously. According to this arrangement, oxygen and hydrogen are not supplied simultaneously. In other words, only when oxygen plasma is generated under the reduced pressure of 50 Torr or less, is hydrogen supplied to reaction chamber 119.

The supply of gas to reaction chamber 101 is performed thereafter. The second embodiment is similar to the first embodiment in that hydro carboniferous source gas is introduced into reaction chamber 101 together with the carrier gas, like helium, and in that hydrocarbon and oxygen are not supplied simultaneously as a safety measure.

The other operations are similar to those of the first embodiment, and plasma 106 is generated by applying the RF voltage to the shower plate, the gas molecules are polymerized according to this plasma operation, and a carbon film is formed on the surface of substrate 103. Also, the exhaust gas from reaction chamber 101 is sent to reaction chamber 119 and is almost completely oxidized and converted into a substance that is hard to be deposited, like CO₂ and H₂O, similar to the first embodiment. Subsequently, according to the same steps as the first embodiment, the generation of the plasma is stopped and substrate 103 is carried outside reaction chamber 101 through slit valve 105, thereby obtaining substrate 103 on which a carbon film is formed.

In the second embodiment, also, a predetermined cleaning process is performed to remove films deposited on the internal wall of reaction chamber 101 and exhaust pipe 132. Similarly to the first embodiment, after plasma containing oxygen is generated in each of two reaction chambers 101, 119, hydrogen is introduced from gas line 129 and gas line 114 at a gas flow of 20 sccm.

Now, since hydrogen is flammable and oxygen increases the susceptibility of substances to burn, plasma processing apparatus 100 according to the present invention is arranged as follows as a safety measure. Specifically, in a situation in which final valve 127 or 112 of the gas line for supplying oxygen is opened, when the pressure is 50 Torr or less and no plasma is generated, final valve 114 and final valve 128 are not opened simultaneously.

After hydrogen is introduced, oxygen radicals and hydroxyl radicals are generated by plasma, thereby removing the product which is adhered and deposited in the reaction chamber and mainly includes carbon. Specifically, the pressure is controlled to several Torr by pressure control valve 123 while introducing oxygen from gas line 114, and the RF voltage is applied between shower plate 108 and stage 102 to generate plasma. Radicals that are generated by this plasma remove carbon films that have adhered onto the surface of shower plate 108, stage 102, and onto the internal wall of reaction chamber 101.

Incidentally, most of the carbon that is oxidized by the radicals becomes CO₂. However, a part thereof reacts in the plasma again and becomes the origin of another product that is easy to be deposited and is represented by a carboxyl group [COOH], in some cases. Even if such a substance is generated upstream of reaction chamber 119, this substance is almost completely oxidized when passing through reaction chamber 119, and thus adherents are prevented being deposited on the elements (the main exhaust valve, the pressure control valve, and the like) downstream of reaction chamber 119.

### Third Exemplary Embodiment

In the second embodiment, oxygen plasma to which hydrogen is added is used to suppress unnecessary carbon deposits. According to the study of the inventors, however, ammonia may be used instead of hydrogen. It becomes clear that nitroxyl radicals as well as hydroxyl radicals are generated by adding ammonia to oxygen plasma and the cleansing capacity is increased by the addition of ammonia to oxygen plasma than by the addition of hydrogen.

In the third embodiment, ammonia can be introduced at the same time as hydrogen is introduced in the second embodiment, and ammonia is supplied from gas line 129, for example, at a gas flow of 40 sccm. Also, since ammonia is flammable and oxygen increases the susceptibility of substances to burn, preferably, ammonia and oxygen are not supplied simultaneously as a safety measure, similar to the above description. The pressure condition may be set so that the value of 50 Torr is a threshold, similar to the above description. In other words, only when oxygen plasma is generated under reduced pressure of 50 Torr or less, is ammonia supplied.

On the other hand, in the cleaning sequence of the second embodiment, after plasma containing oxygen is generated in each of two reaction chambers 101, 119, ammonia is introduced into plasma processing apparatus 100 from gas line 129 and gas line 114 at a gas flow of 500 sccm.

Now, since hydrogen is flammable and oxygen increases the susceptibility of substances to burn, plasma processing apparatus 100 according to the present invention is arranged as follows for safety. Specifically, in a situation in which final valve 127 or final valve 112 of gas lines that are used for supplying oxygen is opened, when the pressure is 50 Torr or less and plasma is not generated, final valve 128 and final valve 114 of gas lines used for supplying ammonia are not opened.

After ammonia is introduced, oxygen radicals, hydroxyl radicals, nitroxyl radicals, and the like are generated by the plasma, and the products that are adhered and deposited in the reaction chamber and mainly include carbon are removed by the action of with these radicals.

Specifically, the pressure is controlled to several Torr by pressure control valve 123 while oxygen is introduced from gas line 114 and the RF voltage is applied between shower plate 108 and stage 102 to generate plasma. Due to the action of the radicals generated by the plasma, carbon films that are adhered to the surface of shower plate 108, stage 102, and to the internal wall of reaction chamber 101 are removed.

Incidentally, most of the carbon that is oxidized by the radicals becomes CO₂. However, a part thereof reacts in the plasma again and becomes the origin of another product that is easy to be deposited, and is represented by a carboxyl group [COOH], in some cases. In this case, also, this substance is almost completely oxidized in reaction chamber 119, and thus adherents are prevented from being deposited on the elements (the main exhaust valve, the pressure control valve, and the like) downstream of reaction chamber 119.

Further, in the above description, ammonia is used instead of hydrogen, however, a mixture of ammonia and hydrogen may be used. Also, ammonia may be used only for cleaning first reaction chamber 101 or may be used only for second reaction chamber 119. Alternatively, hydrogen may be used for cleaning first reaction chamber 101 and ammonia may be used for cleaning second reaction chamber 119, or the reverse thereof is also available.

### Fourth Exemplary Embodiment

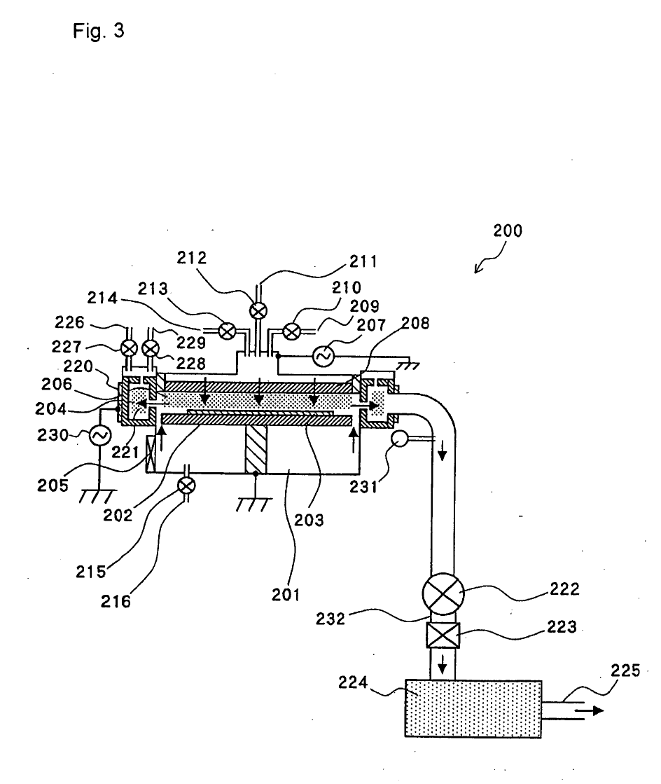

In the arrangement shown in FIG. 2, reaction chamber 119 is arranged between exhaust chamber 104 and main exhaust valve 122, however, there is no limitation on how these arrangements may be applied. FIG. 3 shows another structural example of the plasma processing apparatus according to the present invention. Incidentally, please be sure that the elements to which no explanation is given in the apparatus in FIG. 3 are arranged similar to those of the apparatus in FIG. 2.

In processing apparatus 200 in FIG. 3, exhaust chamber 204 arranged to surround reaction chamber 201 functions as a reaction chamber itself. According to this arrangement, there is no need to clean adherents deposited in exhaust chamber 204 in FIG. 3. In other words, because the exhaust chamber is used as the second reaction chamber, as is, adherents are prevented from being deposited in the exhaust chamber. According to this arrangement, the time for cleaning is shortened, and throughput of the apparatus is improved as the result.

As described in the first to fourth embodiments, the present invention can be used to improve the throughput and the operating rate of the plasma processing apparatus that deposits a film that mainly includes carbon on a substrate.

While preferred embodiments of the present invention have been described using specific terms, such description is for illustrative purposes only, and it is to be understood that changes and variations may be made without departing from the spirit or scope of the following claims.

What is claimed is:

1. A plasma processing apparatus comprising:
a first reaction chamber for performing a first plasma process on an object to be deposited;
a second reaction chamber for performing a second plasma process on an exhaust gas after said first plasma process is performed; and
an exhaust pump for exhausting a gas to the outside after said second plasma process is performed;
wherein said first reaction chamber is connected to said exhaust pump via said second reaction chamber.

2. The plasma processing apparatus according to claim 1, further comprising:
control means for performing a film formation sequence for depositing a film including carbons on said object to be deposited and a cleaning sequence for removing adherents that are adhered to a portion other than said object:
wherein in said film formation sequence, gas containing oxygen is introduced into said second reaction chamber, and then plasma is generated to process the exhaust gas from said first reaction chamber, and in said cleaning sequence, said gas containing oxygen is introduced into said first and second reaction chambers, and then plasma is generated to process said adherents.

3. The plasma processing apparatus according to claim 2, wherein said gas used in both said film formation sequence and said cleaning sequence contains hydrogen in addition to oxygen.

4. The plasma processing apparatus according to claim 2, wherein said gas used in both said film formation sequence and said cleaning sequence contains ammonia in addition to oxygen.

5. The plasma processing apparatus according to claim 2, wherein said film formation sequence comprises the steps of:
generating plasma containing oxygen in said second reaction chamber;
introducing gas containing hydrocarbon into said first reaction chamber;
generating plasma in said first reaction chamber and forming a film containing carbon on said object to be deposited;
stopping plasma generation in said first reaction chamber;
stopping introduction of said gas containing hydrocarbon into said first reaction chamber; and
stopping generation of said plasma containing oxygen in said second reaction chamber.

6. The plasma processing apparatus according to claim 2, wherein said cleaning sequence comprises the steps of:
introducing said gas containing oxygen into said first and second reaction chambers;
generating plasma containing oxygen in said first and second reaction chambers;
stopping plasma generation in said first and second reaction chambers; and
stopping introduction of said gas containing oxygen into said first and second reaction chambers.

7. The plasma processing apparatus according to claim 3, wherein said gas containing hydrogen in addition to oxygen can be introduced into said first and second reaction chambers only when the pressure of said first and second reaction chambers is 50 Torr or less and said plasma that contains oxygen is generated.

8. The plasma processing apparatus according to claim 4, wherein said gas containing ammonia in addition to oxygen can be introduced into said first and second reaction chambers only when the pressure of said first and second reaction chambers is 50 Torr or less and said plasma that contains oxygen is generated.

9. The plasma processing apparatus according to claim 1, wherein said second reaction chamber is formed in a doughnut shape around said first reaction chamber.
